(19) United States
(12) Patent Application Publication
(10) Pub. No.: US 2023/0231592 A1
(43) Pub. Date: Jul. 20, 2023

(54) RADIO DEVICE WITH RESONATOR

(71) Applicant: Nordic Semiconductor ASA, Trondheim (NO)

(72) Inventors: Markus LITTOW, Oulu (FI); Esko NIEMINEN, Oulu (FI)

(73) Assignee: Nordic Semiconductor ASA, Trondheim (NO)

(21) Appl. No.: 17/926,907

(22) PCT Filed: May 28, 2021
(86) PCT No.: PCT/EP2021/064409

§ 371 Date: Nov. 21, 2022

(30) Foreign Application Priority Data
May 28, 2020 (GB) 2008001.6

(51) Int. Cl. H04B 1/38; H03L 1/02; H03L 7/197

(52) U.S. Cl. CPC H04B 1/38; H03L 1/026; H03L 7/1974

(57) ABSTRACT

A radio device comprises a radio transceiver, a resonator, a temperature measurement unit, a frequency synthesiser and a processing system. A temperature signal from the temperature measurement unit, representative of a measured temperature of the resonator, is used to determine an estimated frequency offset for the resonator at the measured temperature using a model stored in a memory of the processing system that relates frequency offset to temperature. A periodic signal from the resonator is provided to the frequency synthesizer, which, in dependence on the estimated frequency offset, is used to generate a periodic local signal. The radio transceiver receives a radio signal comprising a periodic component at a received signal frequency. An error value representative of a difference between the received signal frequency and a frequency of the periodic local signal is determined and used to update one or more parameters of the model stored in the memory.

### BACKGROUND OF THE INVENTION

The invention relates to radio devices with resonators, and methods of operating the same.

Resonators, such as crystal or MEMS (micro-electromechanical system) resonators, are used with oscillator circuits to generate electrical signals having a known frequency. They are used to provide clock signals to digital logic gates in microcontrollers, as well as for generating local-oscillator signals at stable frequencies for heterodyning within radio transmitters and receivers.

The frequency of oscillators used in many radio communication systems needs to be sufficiently accurate and stable to ensure that the radio transmissions stay within the required channel boundaries. For example, in order for user equipment (UE) to transmit according to the HD-FDD (Half-Duplex - Frequency-Division-Duplex) modes of eMTC (Enhanced Machine Type Communication) and NB-IoT (Narrowband Internet-of-Things) 4G LTE™ (Long Term Evolution) standards, the carrier frequency of its radio transmissions must remain within +/-0.1 ppm (parts per million) of the specified centre frequency.

However, the frequency of some resonators is strongly dependent on temperature, with the temperature dependency being determined by the properties of the resonator. For example, in the case of crystal oscillators, the frequency may be dependent on the cut of the crystal, while for a MEMS oscillator the frequency may be dependent on the design and materials of the MEMS resonator. This means that the frequency of an oscillator can vary substantially depending on the instantaneous operating conditions of a radio device, making it challenging to ensure an accurate transmission frequency is used.

Additionally, the characteristic resonant frequency of a resonator can be affected by damage to its structure. For example, stresses within the crystal lattice may affect the characteristic frequency of a crystal resonator. As a result, the frequency of resonators can change over time, in a process referred to as aging.

In full-duplex radio systems, in which radio equipment is able to both transmit and receive signals at the same time, a radio device can receive a radio signal that provides a known, stable reference frequency (e.g. from a cellular network base station). It may use this reference frequency, while simultaneously transmitting a radio signal, to control the frequency of the radio transmissions to ensure that they maintain a fixed spectral relationship to the incoming reference signal. However, when a radio device is transmitting only (e.g. in a half-duplex operation), no such instantaneous reference signal is available.

Therefore, to provide more accurate transmission frequencies in half-duplex radio equipment, it is known to use oven-controlled crystal oscillators (OCXOs) or temperature-compensated crystal oscillators (TCXOs). OCXOs include an electrical heating element alongside the quartz crystal, to shield the oscillating crystal from environmental temperature changes. OCXOs are bulky, expensive and power-hungry compared with conventional crystal oscillators, making them poorly suited to low-cost, battery-powered devices. TCXOs include a temperature sensor and compensation circuitry in the same package as the quartz crystal. TCXOs are less power hungry than OCXOs but are still significantly more expensive than conventional crystal oscillators and may not achieve sufficient accuracy for certain radio requirements—e.g. achieving a +/- 2 ppm accuracy, when some radio standards require +/- 0.1 ppm.

The present invention seeks to provide an alternative approach.

### SUMMARY OF THE INVENTION

From a first aspect, the invention provides a radio device comprising:
a radio transceiver;
a resonator or an interface to a resonator;
a temperature measurement unit or an interface to a temperature measurement unit;
a frequency synthesizer; and
a processing system,
wherein the radio device is configured to:
   receive a temperature signal from the temperature measurement unit, representative of a measured temperature of the resonator;
   use the temperature signal to determine an estimated frequency offset for the resonator, using a model, stored in a memory of the processing system, that relates frequency offset to temperature;
   receive a periodic resonator signal from the resonator;
   provide the periodic resonator signal to the frequency synthesizer;
   control the frequency synthesizer, in dependence on the estimated frequency offset, to generate a periodic local signal from the periodic resonator signal;
   receive a radio signal at the radio transceiver, wherein the radio signal comprises a periodic component having a received-signal frequency;
   determine an error value representative of a difference between the received-signal frequency and a frequency of the periodic local signal; and
   use the error value to update one or more parameters of the model stored in the memory.

From a second aspect, the invention provides a method comprising:
receiving a temperature signal representative of a measured temperature of an resonator;
using the temperature signal to determine an estimated frequency offset for the resonator, using a model that relates frequency offset to temperature;
receiving a radio signal, wherein the radio signal comprises a periodic component having a received-signal frequency;
receiving a periodic resonator signal from the resonator;
using the estimated frequency offset to generate a periodic local signal from the periodic resonator signal;
determining an error value representative of a difference between the received-signal frequency and a frequency of the periodic local signal; and
using the error value to update one or more parameters of the model.

From a further aspect, the invention provides a radio communication system comprising a radio device as disclosed herein and a remote radio transceiver (e.g. a base station), wherein the remote radio transceiver is configured to transmit the radio signals received by the radio device.

Thus it will be seen that, in accordance with the invention, an incoming radio signal is used to calibrate a model of the frequency of the resonator in response to temperature. An incoming radio signal (e.g. from a base station of a cellular telecommunications network) can potentially provide a reliable reference frequency that is not affected by the temperature of the device’s resonator, thereby enabling the radio device to develop an accurate model of the resonator’s behaviour at different temperatures.

This approach allows the characteristics of the particular resonator to be modelled by the radio device. It therefore has the potential to be significantly more accurate than a generic temperature curve, such as a TCXO might use, which is not tailored to the particular resonator.

If, as in some embodiments, the radio device performs these calibration steps repeatedly, at intervals, over a period of time (e.g. over weeks, months or years), the accuracy of the model can be maintained over time, even as the resonator ages. In particular, the model may evolve over time to take account of any changes in the temperature-dependent behaviour of the resonator.

The present approach may, at least in some embodiments, remove the need for the resonator to be packaged with its own temperature compensation circuitry—e.g. being a temperature-compensated crystal oscillator or an oven-controlled crystal oscillator (although these may be used in some embodiments).

In some embodiments, the resonator is a piezoelectric resonator, for example a quartz crystal resonator or a ceramic resonator. In some embodiments, the resonator is a crystal resonator unit. In some embodiments the resonator is in a housing but is not packaged with any temperature sensor or compensation circuitry (such as one or more switchable capacitors). It may simply comprise a crystal and a pair of electrodes in a housing. In other embodiments, the resonator is a MEMS resonator. Again, the MEMS resonator may be in a housing that does not contain a temperature sensor or any temperature compensation circuitry. At least some embodiments may enable a lower-quality resonator to be used than would normally be required in order to provide a required level of accuracy. This can reduce the cost and/or power requirements of the radio device.

By using the model to control a frequency synthesizer, temperature compensation can, at least in some embodiments, advantageously be made using digital logic and/or software alone, e.g. without the need to have a bank of capacitors that can be switchably controlled to change the resonant frequency of the crystal. This can enable finer-grained control of the frequency, and may also keep the size and cost of the radio device down. (However, other embodiments may combine digital and analogue compensation mechanisms.)

The radio device may be configured to use the model for transmitting (and/or receiving) radio signals. The radio device may be configured to perform the updating of the one or more parameters when in a calibration state. The radio device may be configured to use the model to transmit (and/or receive) a radio signal when in a running state, distinct from the calibration state.

In particular, the radio device may be further configured to:
receive a second temperature signal from the temperature measurement unit, representative of a second measured temperature of the resonator;
use the second temperature signal and the model stored in the memory of the processing system to determine a second estimated frequency offset for the resonator; and
use the second estimated frequency offset for transmitting or receiving a radio signal.

The radio transceiver may be configured to transmit a radio signal according to a half-duplex radio protocol, such as NB-IoT or half-duplex eMTC. The present approach may be particularly advantageous in such situations, since, unlike with full-duplex communication, there is no possibility for the radio device to use an incoming radio signal to provide an instantaneous timing reference for synchronizing a simultaneous radio transmission. Instead, the radio device may be configured to use the resonator for generating the transmitted radio signal—e.g. for generating a local-oscillator signal to be input to a mixer for up-mixing a baseband signal to radio frequency (RF).

The periodic local signal may be used for transmitting or receiving a radio signal. In particular, the periodic local signal may be a local-oscillator signal which the radio device may be configured to provide to the radio transceiver—e.g. as input to a mixer in the radio transceiver. The radio transceiver may be configured to use the local signal to up-mix a signal, e.g. to up-mix a baseband or intermediate-frequency signal to radio frequency, for transmission from a radio antenna. When receiving a radio signal, the radio transceiver may be configured to use the local signal to down-mix the received radio signal, e.g. to an intermediate frequency or to baseband.

In some embodiments, the local signal may be used to tune the radio receiver to receive a radio signal before starting to receive the radio signal. Then, while the radio signal is being received, the radio device may instead control the frequency synthesizer in dependence on a frequency of the received signal itself—e.g. using an automatic frequency control (AFC) unit in the radio transceiver.

The radio device may be or comprise an integrated-circuit (IC) device. It may be or comprise a semiconductor chip, such as a system-on-chip (SoC). The resonator and/or temperature measurement units may be off-chip components, while the processing system and at least part of the radio transceiver may be integrated on a single chip or may share a common IC package. However, in some embodiments, the temperature measurement unit may be integrated with the processing system—e.g. comprising a silicon bandgap temperature sensor. The resonator may be driven by oscillator circuitry which may be integrated on the same chip as the processing system. In some embodiments, the radio device may be a SoC. In other embodiments, it may be a larger device such as a wireless sensor or a set of headphones. It may comprise a battery, user interface, etc. The radio transceiver may comprise or have an interface to a radio antenna.

The radio device may be configured to receive and transmit data over an LTE™ radio network.

The radio device may comprise the temperature measurement unit, which may be located adjacent or proximate to the resonator, so as to sense the temperature of the resonator. The resonator (e.g. quartz crystal) may be coupled directly to pins of an integrated-circuit chip that comprises the temperature measurement unit (and optionally the processing system too). In some embodiments, the resonator and temperature measurement unit may be housed in a common housing (e.g. a metal case). However, in other embodiments, the temperature measurement unit may be packaged separately from the resonator—e.g. outside a housing of the resonator. The temperature measurement unit may comprise a thermistor or other thermometer, which may be arranged for measuring a temperature proximate to the resonator. In some embodiments, the temperature measurement unit may comprise one or more further environmental sensors, such as an atmospheric pressure sensor and/or a humidity sensor. The radio device may receive an analogue or digital temperature signal from the temperature measurement unit. Where the radio device comprises the temperature measurement unit, such receiving is internal within the radio device—e.g. being received by a pin or pad of an IC chip comprising the processing system.

The processing system may comprise one or more processors and memory storing software instructions for execution by the one or more processors. The software may comprise instructions for carrying out any part of all of the processing operations disclosed herein. Alternatively or additionally the processing system may comprise dedicated hardware logic for carrying out any part of all of the processing operation disclosed herein. It will be appreciated that steps disclosed herein may, wherever appropriate, be implemented by software or by hardware in any appropriate proportion.

The processing system may be configured to use the model to determine the estimated frequency offset from the temperature signal in any appropriate way. The estimated frequency offset may represent an absolute value (e.g. in Hz) or a relative value (e.g. in ppm); it may be relative to a nominal or characteristic frequency of the resonator. It may be encoded in any appropriate way. The model may represent absolute or relative frequency error (i.e. frequency offset divided by absolute frequency) as a function of temperature. The model may represent frequency error using sum, difference, or multiplication functions, or using a neural network, or any combination of these. In some embodiments frequency error may be represented by a polynomial function, such as a third or fourth order polynomial function; however polynomials of higher or lower orders may be used depending on the temperature-frequency drift characteristics of the resonator. In some embodiments, the model may comprise one or more parameters for a predetermined equation or model function, such as a polynomial function. The processing system may evaluate the equation numerically, for a particular measured temperature input, to determine an estimated frequency offset. The equation may be a cubic function. In some embodiments, the model may comprise parameters representing a look-up table and the processing system may be configured to perform a look-up operation based on the measured temperature to determine the estimated frequency offset.

In some embodiments, the model may additionally relate frequency offset to one or more additional environmental factors, such as atmospheric pressure or humidity. The estimated frequency offset may then be determined not only using the temperature signal but also a signal representative of a further environmental factor, such as atmospheric pressure and/or humidity.

Parameters of the model may, in some embodiments, be stored in non-volatile memory, e.g. flash memory. In this way the model is retained even if the radio device loses power.

In some embodiments, the radio device may store a model comprising one or more initial parameters—e.g. loaded by a manufacturer of the radio device—which may represent an initial or default model. These may be supplemented or replaced by one or more new parameters, derived from received radio signals and measured temperatures, as the radio device is used.

The frequency synthesizer may generate the periodic local signal by scaling up the periodic resonator signal. The frequency synthesizer may be a fractional frequency synthesizer. The radio device may use the estimated frequency offset to control a scaling factor applied to the periodic resonator signal by the frequency synthesizer. In some embodiments, the estimated frequency offset, or a value or signal derived therefrom, is provided as input to a fractional divider in the frequency synthesizer.

The periodic component of the received radio signal may be the carrier frequency of the radio signal. Alternatively, it could be a periodic pattern that is modulated on the radio signal—e.g. a sequence of timing symbols or data packets encoded by the radio signal. The received signal may be transmitted from a cellular base station, although this is not essential.

In some embodiments, the error value may equal or be determined from the difference between the received-signal frequency and the fundamental frequency of the periodic local signal generated by the frequency synthesizer, or may equal or be determined from this difference minus a constant value (e.g. minus an intended frequency offset between a carrier frequency and an intermediate frequency). The processing system may be configured to subtract the received-signal frequency value from the fundamental frequency, or vice versa. In some embodiments, the error value may be a relative, rather than an absolute, frequency value (e.g. representing a Δf/f ppm error). It may equal a difference, as above, divided by a reference frequency value, which may be the received-signal frequency or the local-signal frequency. Calculating a relative error value may facilitate comparing the error value with a relative frequency offset estimated by the model.

In some embodiments, the error value may be determined from the absolute or relative difference between the received-signal frequency and the fundamental frequency of the period local signal, after one of these frequencies is multiplied by a constant factor, wherein the constant factor may be greater or less than one. In this way, the error value may represent a residual offset error after an intended scale factor between the frequencies has been accounted for.

In some embodiments, the error value may be generated at least in part using an automatic frequency control (AFC) unit in the radio transceiver.

In some embodiments, the processing system may subtract the error value from the estimated frequency offset (or vice versa) to generate an adjusted estimated frequency offset, which may be used to update the model stored in the memory. In some embodiments both the error value and the estimated frequency offset are relative frequency offset values.

The error value may be used to update the model in any of various different ways, which may depend on the nature of the model. The measured temperature associated with the error value may also be used when updating the model.

The error value, or data representative thereof or derived therefrom (e.g. an adjusted estimated frequency offset, as described above), may be stored in a buffer. The buffer may be arranged to store one or more such values, which may be obtained at different times and potentially at different resonator temperatures. The buffer may also store respective temperature data, associated with each error value. In some embodiments, the buffer may also store respective environmental data, such as atmospheric pressure or humidity, associated with each error value.

The radio device may be configured to determine error values at intervals, which may be at regular or irregular intervals, such as every time a particular type of radio signal is received. The device may be configured to update the model at regular intervals and/or when one or more conditions are met. In some embodiments, the device may not always update the model every time an error value is calculated—for example, if it determines that the error value is below a threshold value. This may help reduce power consumption.

In some embodiments, the processing system may update one or more parameters of the model by inputting the error value (and optionally other buffered data) into an optimization process. One or more pairs of error values and associated measured temperatures may be used to perform a cost minimization process in order to calculate one or more updated parameters for the model. The processing system may, in some embodiments, determine the one or more parameters by solving a least squares problem to minimize a cost function, for example using a gradient descent process. The cost function may represent a mean difference squared between a model function (e.g. a polynomial function, such as a cubic or quartic function) and the buffered data.

In some embodiments, the processing system may implement a gradient descent process with a momentum term. It may use exponentially weighted averaging when calculating the one or more updated parameters—e.g. by storing a previous value and a current value of a parameter in the memory, and calculating a new value of the parameter in dependence on the stored previous and current values.

In some embodiments, the processing system is configured to constrain one or more of the parameters of the model function (e.g. a polynomial coefficient) to be above a respective minimum value and/or below a respective maximum value. The minimum and maximum values may be based on a characteristic of the resonator. For example in embodiments in which a crystal is used, the minimum and maximum values may be based on the cut angle or cut type (e.g. AT-cut or BT-cut) of the oscillating crystal.

In some embodiments, the model may be a linear combination of two predetermined polynomial functions of temperature—e.g. two quadratic or cubic polynomials. The predetermined functions may be set based on the upper and lower bounds of expected variations in the properties of resonators that arise during manufacturing. Parameters representing the two predetermined polynomial functions may be stored in the memory; in some embodiments they may be read-only values. The processing system may be configured to use the error value (or a set of error values) to update a parameter representing one or more coefficients of the linear combination. The predetermined polynomial functions may be preloaded in the device during manufacturing. The model may then be represented as a linear combination of the two polynomial functions.

In some embodiments, a pair of first and second polynomial functions determine pointwise upper and lower bounds for the model, at least over a temperature range of interest,. The model may represent a function equal to i) the first polynomial function, plus ii) the difference between the second and first polynomial functions multiplied by a variable factor less than one. The variable factor may be stored in the memory as a parameter of the model. In some embodiments, the model may be represented solely by this one value, which can lead to a particularly memory efficient implementation. The processing system may use an error value and an associated measured temperature to calculate an updated value for the variable factor. A plurality of buffered error values and temperatures may also be used, e.g. by calculating an updated value for each buffered pair, and then mean averaging the updated values to determine a final value for the variable factor.

In some embodiments, the processing system may implement a least-squares process to fit a function of predetermined type—e.g. a polynomial function—to a set of error values and associated measured temperatures. The model may then be represented in the memory by the coefficients of the function.

In some embodiments, the processing system may at times (e.g. when updating the model for the first time), use one or more (e.g. three) predetermined auxiliary values (which may be based on a fixed characteristic of the resonator, such as the cut angle in embodiments employing a crystal oscillator), in addition to one or more calculated error values and measured temperatures, when updating the model. This can be useful when the device has not yet had time to collect a range of calibration values spanning a wide temperature range. The auxiliary values may be excluded when updating the model once a threshold number of error values have been determined.

Features of any aspect or embodiment described herein may, wherever appropriate, be applied to any other aspect or embodiment described herein. Where reference is made to different embodiments or sets of embodiments, it should be understood that these are not necessarily distinct but may overlap.

### BRIEF DESCRIPTION OF THE DRAWINGS

Certain preferred embodiments of the invention will now be described, by way of example only, with reference to the accompanying drawings, in which:

FIG. 1 is a schematic diagram of a cellular communication system including a radio device embodying the invention;

FIG. 2 is a schematic diagram of a fractional frequency synthesizer and crystal resonator of the radio device;

FIG. 3 is a flow chart of steps of a transmit operation performed by the radio device;

FIG. 4 is a flow chart of steps of a receive operation performed by the radio device; and

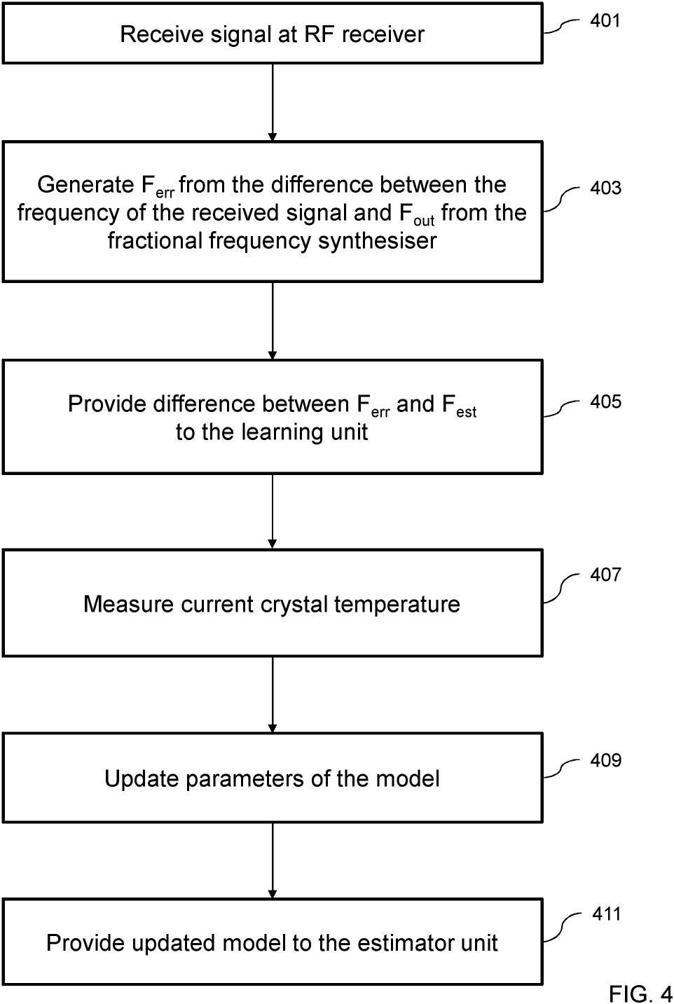

FIG. 5 is a graph of relative frequency offset against temperature for crystal oscillators at a range of cut angles.

### DETAILED DESCRIPTION

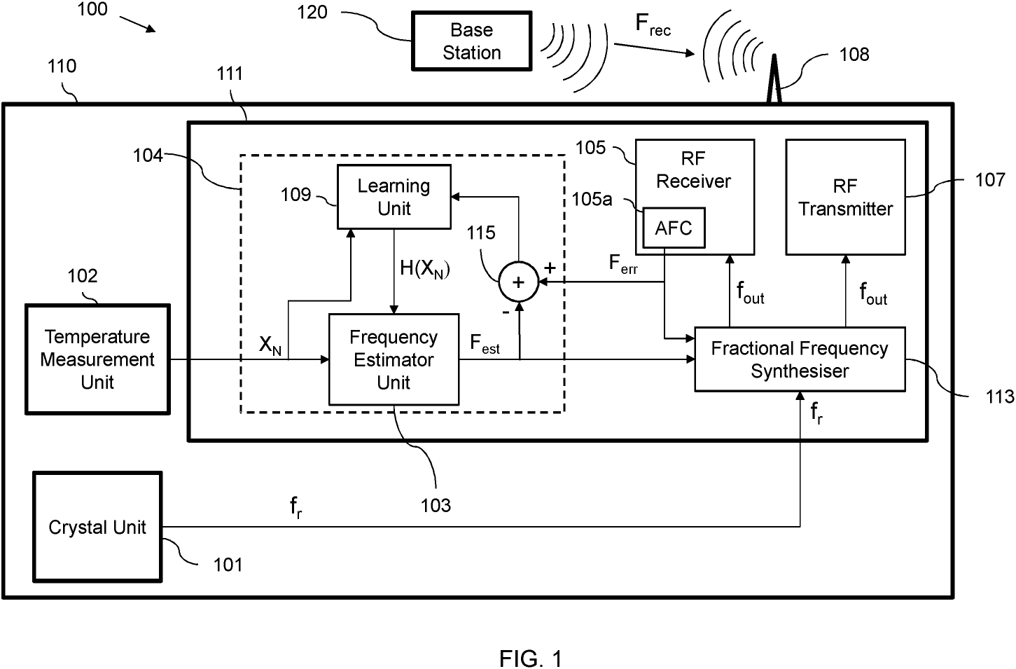

FIG. 1 is a schematic diagram of a Long Term Evolution (LTE) cellular communication system 100, embodying the invention, including a base station (eNodeB) 120 and a user-equipment (UE) radio device 110.

The radio device 110 implements a local frequency compensation scheme and also embodies the invention.

The radio device 110 may be a wireless Internet-of-Things (IoT) sensor or any other appropriate electronic device.

The radio device 110 includes a system-on-chip (SoC) 111, which is connected to an off-chip crystal unit 101 and a temperature measurement unit 102, arranged to measure the temperature of the crystal unit 101. The crystal unit 101 in this example is a bare resonator device that does not contain any driver circuitry nor any internal temperature compensation mechanism. The oscillator driving circuitry is integrated on the SoC 111.

While FIG. 1 shows a crystal unit 101, in other embodiments a MEMS resonator, or other type of resonator or packaged oscillator, could be substituted for the crystal unit 101 without altering the relevant functioning of the radio device 110 as described herein.

The radio device 110 may include conventional elements such as a battery, sensors, displays, data interfaces, user interfaces, discrete electronic components (e.g. capacitors and inductors), further integrated-circuit chips, etc., which are omitted from FIG. 1 for the sake of simplicity.

The SoC 111 comprises a processing system 104 which may contain one or more processors and associated memory for executing software to control the radio device 110. The processing system 104 may include a microcontroller and/or one or more application processors such as an Arm™ Cortex™ processor and/or a digital signal processor (DSP). In some embodiments it may additionally or alternatively contain application-specific logic. It may comprise RAM and flash memory..

The SoC 111 further comprises a radio frequency (RF) receiver 105 and an RF transmitter 107 (together providing a radio transceiver as disclosed herein). These are capable of being operated in half-duplex NB-IoT and eMTC modes, in which transmit and receive operations are carried out at different times, rather than simultaneously. The RF transmitter 105 and RF receiver 107 may in some embodiments share common circuitry or components. They may be connected to various off-chip elements (not shown) such as a power amplifier, inductors. They communicate with the base station 120 through a common antenna 108.

The SoC 111 also includes a frequency estimator unit 103, a learning unit 109, and a radio-frequency (RF) fractional frequency synthesizer 113. It may also contain conventional peripherals, such as timers, interfaces, security components, power management circuitry, etc. The frequency estimator unit 103 and/or the learning unit 109 may be software components executing on one or more processors of the processing system 104, for example on a digital signal processor or an application processor. In other embodiments, the frequency estimator unit 103 and/or learning unit 109 may be implemented using dedicated hardware logic, or as a combination of both software and hardware.

The crystal unit 101 and the fractional frequency synthesizer 113 together form an RF frequency generator 200, for providing a radio-frequency local-oscillator signal fₒᵤₜ to the RF receiver 105 and the RF transmitter 107. The receiver 105 can input the signal fₒᵤₜ to a mixer to down-mix an incoming radio signal received at the antenna 108, while the transmitter 107 can use it to up-mix a baseband signal (e.g. provided to the RF transmitter 107 by the processing system 104) to an RF electrical signal for transmission from the antenna 108.

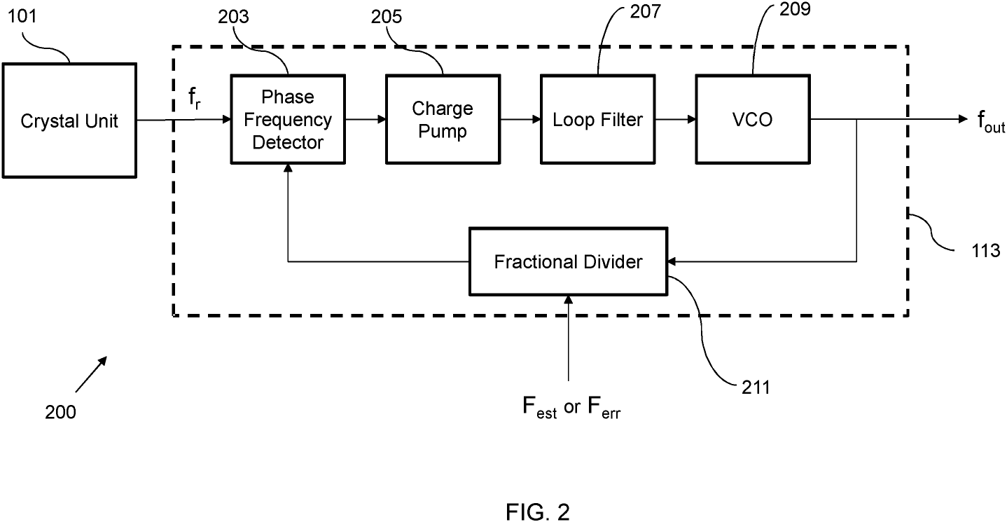

FIG. 2 shows the frequency generator 200 in more detail.

When powered on, the crystal unit 101 generates an oscillating reference signal, fᵣ, e.g. of frequency fᵣ = 32 MHz, which is sent to the fractional frequency synthesizer 113. The fractional frequency synthesizer 113 is a highly-accurate, charge-pump phase-locked loop (PLL) synthesizer, which generates an output signal, fₒᵤₜ, at a desired output frequency, fₒᵤₜ, e.g. 2 GHz, derived from the reference signal fᵣ. The output frequency fₒᵤₜ will typically be set by the processing system 104 depending on the radio band it is desired to transmit or receive on.

The frequency synthesizer 113 comprises a phase frequency detector 203, a charge pump 205, a loop filter 207, a voltage controlled oscillator (VCO) 209, and a fractional divider 211.

The phase frequency detector 203 receives the reference signal fᵣ from both the crystal unit 101 and a feedback signal from the fractional divider 211. It produces an error signal proportional to the difference between the phases of the two signals. This error signal is passed to the charge pump 205, which generates positive and negative current pulses that are passed to the loop filter 207. The loop filter 207 removes unwanted noise, e.g. from the phase detector 203, before the signal is fed to the voltage controlled oscillator (VCO) 209. The VCO 209 generates an output signal fₒᵤₜ with an output frequency fₒᵤₜ.

The output signal fₒᵤₜ is fed to a fractional divider 211 and back to the phase frequency detector 203, producing a negative feedback loop. If the output frequency fₒᵤₜ drifts, the phase error signal will increase, thus driving the VCO 209 in the opposite direction and reducing the error.

The fractional divider 211 is implemented using dedicated transistors and logic, and is configurable by software executing on the processing system 104 through a register interface. At any moment, the fractional divider 211 divides the output frequency fₒᵤₜ by an integer value, thereby causing fₒᵤₜ to be that integer multiple of the reference frequency fᵣ. However, the fractional divider 211 can dynamically change this integer value over time, e.g. between values N and N+1, such that the average division over time is fractional. If, out of B cycles, fₒᵤₜ is divided by N+1 for A cycles, and by N over B minus A cycles, the average division corresponds to the fraction N+A/B.

Thus, by appropriately controlling the fractional divider 211, the frequency generator 200 can generate a signal fₒᵤₜ with an output frequency

$${f}_{o u t} = {f}_{r} ∗ \left(N + \frac{A}{B}\right)$$

where N, A, and B are non-negative integers obeying 0 ≤ A < B, and where N and A relate to the integer and fractional components used to set up the fractional divider 211, and where B is a fixed value determined by the design of the frequency synthesiser.

In this way a large number of output frequencies are achievable, each separated by a minimum step value. This allows a wide range of radio channels to be tuned, with very fine granularity.

The minimum achievable step value between output frequencies occurs for A =1, N = 0. Assuming a value of B = 2²⁴, output signals can be generated from the voltage controlled oscillator 209 with a minimum difference between them of N / B = 32/2²⁴ MHz, i.e. around 2 Hz.

For example, for a desired output frequency from the fractional frequency synthesizer of fₒᵤₜ = 965 MHz, and a value of B = 2²⁴, the integer and fractional components can be determined as N+A/B = fₒᵤₜ/fᵣ = 965/32=30.15625 Hz, by taking the integer component to be the value of N, i.e. N = 30, and the fractional part as equal to A/B, i.e. A/B = 0.15625. The value of A required to produce an output frequency of 965 MHz can be determined to be A = 0.15625 * 2²⁴, i.e. A = 2,621,440. Using these values of A and N, the chosen output frequency fₒᵤₜ = 965 MHz can be generated. The generated output frequency may be calculated using software executing on a processor of the processing system 104, however it could also be calculated using suitable hardware.

This loop therefore ensures that the output frequency fₒᵤₜ remains a chosen fractional multiple of the frequency of the crystal unit 101.

Although the minimum step value is, in principle, determined based on the value of B and the frequency of the crystal unit 101, in practice, the system is limited by the stability of the crystal unit 101. For example, a typical stability of the crystal may be +/-1 ppm, which for the exemplary 32 MHz crystal unit 101 would be around +/-32 Hz. If the crystal unit frequency drifts within this range as a result of a temperature changes, and increases by 1 ppm, e.g. 32 Hz, then applying the fractional frequency operation above, an erroneous output frequency fₒᵤₜ is obtained of fₒᵤₜ = 965,000,965 Hz, i.e. 965 Hz too high.

Such a large drift would cause problems in applications such as LTE radio communication, where the half-duplex specifications for the eMTC and NB-IoT standard require that the user-equipment transmission frequency stay within +/-0.1 ppm relative to base station frequency. However, the radio device 110 addresses this problem by compensating numerically for any temperature-induced offset in the oscillator output.

To achieve this, the fractional divider 211 of the fractional frequency synthesizer 113 employed in the radio device 110 additionally receives a data input Fₑₛₜ (e.g. a floating point value) from the frequency estimator unit 103, which it uses in the generation of the output frequency fₒᵤₜ as follows.

The frequency estimator unit 103 is configured to generate an estimate, Fₑₛₜ, of the relative frequency offset (i.e. the frequency offset divided by the nominal frequency) resulting from the current operating temperature T of the crystal unit 101, and to provide this estimate to the fractional frequency synthesizer 113. The estimated relative frequency offset Fₑₛₜ is used in the fractional divider 211 to compensate for any actual temperature-induced frequency offset that might be present in the signal fᵣ output by the crystal unit 101. In this embodiment, the frequency estimator unit 103 is implemented using software executing on a processor of the processing system 104, although in other embodiments it could be implemented using dedicated hardware logic, or a combination of both software and hardware.

The frequency generator 200 can output a local-oscillator signal, fₒᵤₜ, to the radio receiver 105 or the radio transmitter 107, as needed, having a desired frequency fₒᵤₜ.

The radio device 110 operates differently depending on whether it is acting in a half-duplex transmit mode or a half-duplex receive mode. In particular, when in receive mode, it may at times enter a calibration state, whereas it is in a normal running state (i.e. not the calibration state) during transmit mode and at other times in receive mode.

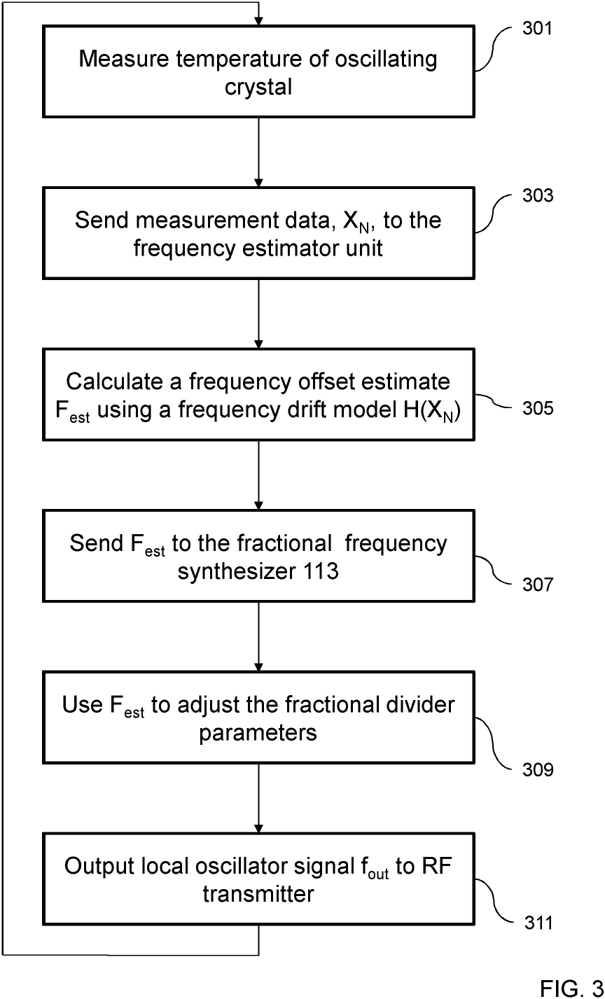

During transmission operations, the radio device 110 operates according to the process shown in FIG. 3. In step 301, the temperature measurement unit 102 measures the temperature of the crystal unit 101. In step 303 the temperature measurement unit 102 provides the measured temperature to the frequency estimator unit 103, as part of an input variable vector X_{N}. The input variable vector X_{N} may also optionally include information related to other variables, such as an atmospheric pressure measurement determined from a barometric pressure sensor in the radio device 110.

In step 305 the frequency estimator unit 103 applies the received variable vector X_{N} as input to a frequency-drift model H(X_{N}), which is used to determine an estimated relative frequency offset value Fₑₛₜ for the measured temperature (and optionally for other variables such as atmospheric pressure). The model H(X_{N}) may be implemented in any appropriate way. In some embodiments, the frequency estimator unit 103 evaluates a polynomial function of the temperature, e.g. a cubic function, where the parameters of the polynomial function are stored in a memory of the frequency estimator unit 103. The parameters may have been received previously from the learning unit 109, as described below. In other embodiments, the model may be stored as a look-up table—this may be more efficient if the temperature measurement unit 102 can output only a relatively few different values, e.g. temperature to the nearest 1° C. or 5° C.

In step 307 the relative frequency offset value Fₑₛₜ is provided to the fractional divider 211 of the frequency synthesizer 113. In step 309 the fractional divider 211 uses it to adjust the default values of N and A (corresponding to a desired output frequency fₒᵤₜ) to compensate for the estimated offset in the signal fᵣ received from the crystal unit 101. The integer part of the ratio fₒᵤₜ/Fₑₛₜ is used as the adjusted N value, while the remainder is multiplied by the fixed value B, and the integer component of the resulting value is used as the adjusted A value.

For example, in the case of a desired output frequency of 974 MHz, a fixed value of B=2²⁴, a nominal frequency value fᵣ = 32,000,000 Hz, and a relative frequency offset value Fₑₛₜ = 32,000,150 the offset frequency is 150 Hz higher than the nominal frequency. The ratio fₒᵤₜ/ Fₑₛₜ = 974,000,000/32,000,150 ≈ 30.437357325, from which the value of N can be taken as the integer component, N = 30. The remainder 0.437357325 is then multiplied by the fixed value of B, resulting in a value of 0.437357325*B = 7,337,638.3107072.00. The integer component of this value is then taken as the adjusted value of A, i.e. A = 7337638. The frequency synthesizer 113 then uses these values to output the frequency fₒᵤₜ = Fₑₛₜ*(7337638/2²⁴) ≈ 973,999,999.41 Hz, which is 0.59 Hz less than desired 974 MHz, achieving the desired accuracy of < 0.1 ppm.

In step 311, the frequency synthesizer 113 outputs the adjusted local-oscillator RF signal fₒᵤₜ, derived from the incoming crystal signal fᵣ, to the RF transmitter 107.

This process may be performed repeatedly during a transmission operation, i.e. looping back round to step 301 and step 311, so as to adjust the local oscillator signal fₒᵤₜ dynamically in response to on-going changes in the temperature of the crystal 101 during a radio transmission.

During receive operations, the radio device 110 may, at times, enter a calibration state in which it uses the stable carrier frequency of a radio signal received from the base station 120 to update its frequency-drift model H(X_{N}). It may enter the calibration state every time it receives a relevant radio signal, or it may do so according to a schedule and/or based on other factors.

The RF receiver 105 contains an automatic frequency control (AFC) unit 105a which determines an actual relative frequency offset Fₑᵣᵣ as the difference between the carrier frequency F_{rec} of the incoming signal from the base station 120 and the local-oscillator frequency fₒᵤₜ being generated by the fractional frequency synthesizer 113 (plus any intermediate frequency, unless the receiver is a zero-IF receiver), expressed as a fraction of the local-oscillator frequency fₒᵤₜ (e.g. in parts per million).

This relative offset Fₑᵣᵣ is provided to the fractional divider 211 of the fractional frequency synthesizer 113 which uses it to apply correction to the local oscillator signal fₒᵤₜ during the receive options. However, the relative offset Fₑᵣᵣ is also used to train the model H(X_{N}), for use during subsequent transmit operations, by comparing an estimated relative frequency offset Fₑₛₜ, calculated by the frequency estimator unit 103 from the current model H(X_{N}), with the actual relative offset, Fₑᵣᵣ, measured during a receive operation.

The frequency of the transmitted signal from base station 120 is significantly more precise than the signal generated by the crystal unit 101 employed in the radio device 110 of the present invention. For example, the base station signal may be generated using a highly stable temperature controlled crystal oscillator (TCXO), as the power and cost requirements of the base station 120 are not constrained as they are for the radio device 110.

In step 401, the RF receiver 105 receives a radio signal, F_{rec}, from the base station 120, having a carrier frequency F_{rec}, which the receiver 105 tunes using an initial local-oscillator signal, fₒᵤₜ, generated by the frequency synthesizer 113. The initial signal, fₒᵤₜ, is generated using an estimated relative frequency offset, Fₑₛₜ, provided by the frequency estimator unit 103. The offset may be calculated from the current model H(X_{N}) using the current crystal temperature, as measured by the temperature measurement unit 102.

In step 403, the AFC 105a compares the received signal F_{rec} with the signal fₒᵤₜ output from the fractional frequency synthesizer 113, and generates an error signal Fₑᵣᵣ representative of the relative frequency error between them. The error signal Fₑᵣᵣ is fed back to the frequency synthesizer 113 which uses it to adjust the output frequency fₒᵤₜ, as required, in order to maintain frequency synchronization with the base station 120 while in the receive mode.

In step 405, the relative frequency error signal Fₑᵣᵣ is also input to a subtraction unit 115, along with the estimated relative frequency offset, Fₑₛₜ, generated by the frequency estimator unit 103 based on the current crystal temperature from the temperature measurement unit 102. The subtraction unit 115 calculates the difference (if any) between the estimated relative offset error, Fₑₛₜ, and the actual relative offset error, Fₑᵣᵣ and provides this to the learning unit 109.

In step 407, the learning unit 109 acquires an up-to-date crystal temperature measurement, T. It can use this to calculate the current value of Fₑₛₜ.

In some embodiments, the values of Fₑᵣᵣ and Fₑₛₜ may both be provided directly to the learning unit 109.

In step 409, the learning unit 109 determines if the difference between the values of Fₑᵣᵣ and Fₑₛₜ is above a threshold value (for example 0.5 ppm), and, if so, updates the model H(X_{N}) for the current temperature T using a learning algorithm (explained in more detail in the following), before providing the updated model parameters to the frequency estimator unit 103 in step 411, for later use in determining another Fₑₛₜ value using the updated frequency drift model H(X_{N}) during transmission operations. In some other embodiments there may be no comparison against a threshold value and the model parameters may always be updated.

This calibration process may be repeated multiple times, at intervals, during a single radio reception operation, or it may be performed more occasionally—e.g. once every hour, or once a day, if the device 110 is performing a receive operation. In some embodiments, calibration may be performed more frequently (e.g. hourly) when the device 110 is first initialised from new, until measurements spanning a minimum range of crystal temperatures have been obtained, and may thereafter perform calibration operations less frequently (e.g. weekly, monthly or yearly), so that the model adapts as the crystal 101 slowly ages. In some embodiments, calibration may be performed in response to the relative offset error Fₑᵣᵣ being determined to be greater than a predetermined threshold value. The time interval in which Fₑᵣᵣ is likely to increase is strongly dependent on the conditions experienced by the crystal 101, which may accelerate the aging of the crystal 101.

When preparing to receive a radio signal—e.g. on switching from a transmit mode to a receive mode—the radio device 110 may follow the same process described with reference to FIG. 3, but outputting the local-oscillator signal fₒᵤₜ to the RF receiver 105 (instead of to the RF transmitter 107) in the final step 311. In this way, an initial local-oscillator signal can be generated which should be closely matched to the actual incoming carrier signal. Once the radio signal starts being received, the AFC 105a can track the actual carrier frequency, as already explained above.

By updating the parameters of the frequency drift model H(X_{N}) based on a locally measured oscillator temperature and a precise received frequency from the base station 120, an up-to-date model of the oscillating frequency of the crystal unit 101 can be developed and maintained. Over time, the model will be trained on measured data points spanning the full range of operating temperatures that the crystal 101 actually experiences. Also, through this on-going learning process, the model H(X_{N}) will be updated to reflect the changing characteristics of the crystal unit 101 over its lifetime.

The implementation of the learning algorithm will now be explained in more detail.

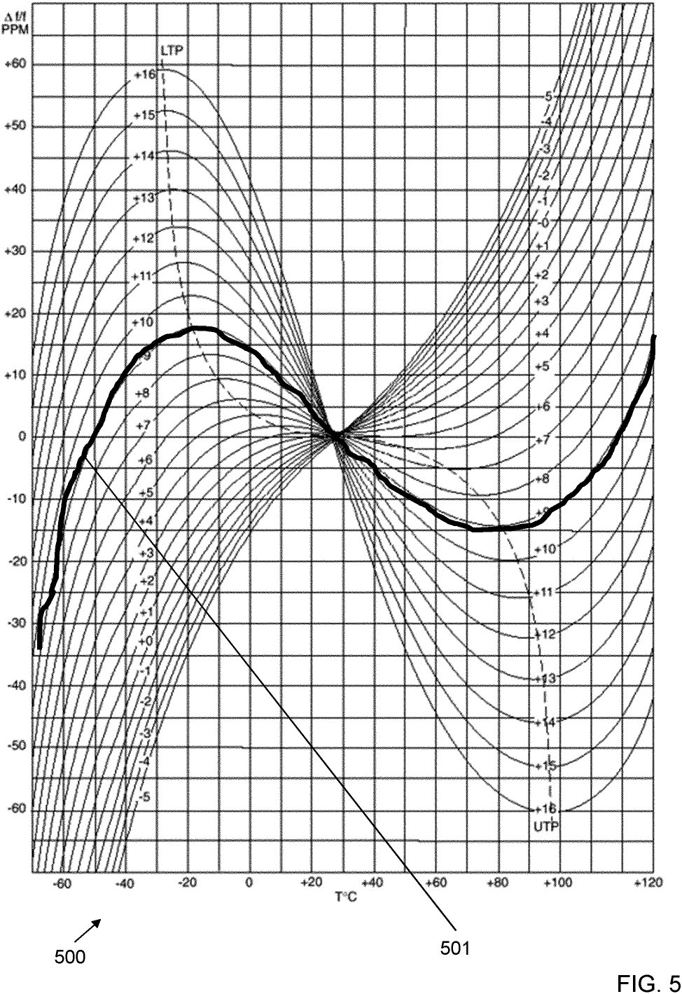

For a crystal oscillator, the frequency drift with temperature is dependent on the cut of the crystal, i.e. the angle at which the crystal has been cut relative to the planes of lattice structure of the crystal. This variation of frequency with temperature is demonstrated in FIG. 5, which shows the relative frequency offset Δf/f in parts per million against temperature, for a variety of cut angles (referenced to a predefined temperature of 27° C., at which there is no temperature related offset by definition).

The frequency offset curves in FIG. 5 show how the relative frequency offset changes for different cutting angles relative to an absolute cutting angle of 35°15′ from the Z-axis of the crystal (the “AT” cut angle). Each curve represents a different cutting angle with an indicated angular difference (in minutes, i.e. 1/60°) relative to the AT-cut angle.

Due to variability in crystal processing, a desired cutting angle may only be achievable within a particular tolerance. Also, in practice, the behaviour of a crystal against temperature does not perfectly follow the smooth curves shown in FIG. 5. Instead, there will be slight deviations from the idealised model. It may have systematic and/or random frequency dips. Also, there can be some error in the measurements from the temperature sensor 102 and from the AFC 105a. An example of this variability is shown by curve 501, which illustrates how the relative frequency offset with temperature does not follow the curves exactly, but has some variability, specific to each individual crystal. The present empirical modelling approach can help to compensate for this kind of variation.

The shape of the temperature-related frequency drift curves shown in FIG. 5 comes from the particular material physics of the crystal, and is dependent on the cutting angle of the crystal. The shape of the temperature-related frequency drift curves can generally be modelled with reasonable accuracy using a polynomial function, typically a polynomial function of degree two, three or four. For example, the temperature-related frequency drift curves for AT-cut type crystals can be accurately modelled using a third order polynomial function. In some embodiments, a MEMS resonator may be used in place of a crystal resonator, in which case the temperature-related frequency drift curves will not depend on the cut angle, but rather the specific frequency-temperature profile of the MEMS resonator used. In such embodiments, the operations carried out by the learning unit 109 apply equally, however the exact shape of the functions used will vary depending on the nature of the resonator.

At least in some embodiments, the relative frequency error Δf/f as a function of temperature around a reference temperature T₀ can be modelled by the learning unit 109 using the following equation:

$$\frac{Δ f}{f} = a {\left(T - {T}_{0}\right)}^{3} + b {\left(T - {T}_{0}\right)}^{2} + c \left(T - {T}_{0}\right) + d$$

This relationship is typically valid for temperatures between -60° C. ≤ T ≤ 120° C. The reference temperature T₀ is generally in the range 20-35° C. In some examples the reference temperature may be 27.5° C. The scale of the relative frequency error Δf/f is typically of the order of parts per million (ppm).

The values of a, b, c and d are stored in a memory of the learning unit 109 and/or of the frequency estimator unit 103, as the parameters of the model H(X_{N}) used by the frequency estimator unit 103 to estimate the relative frequency offset during radio transmission. The learning unit 109 updates these parameters at intervals, when one or more new samples have been collected from the temperature measurement unit 102 and the RF receiver 105.

Custom initial values for a, b, c and d could be measured for each individual resonator, e.g. crystal 101, but this would incur a significant cost and time expenditure. Additionally, as the values of these coefficients change with time, as the resonator ages, they are not perpetually valid. The learning algorithm aims to determine accurate values of each of the coefficients a, b, c, and d for the unique resonator, employed in the radio device 110 (e.g. crystal 101 in this embodiment).

In general, the dependence on temperature can be modelled by a polynomial function, depending on the characteristics of the resonator. For crystal resonators, polynomials of degree three are most appropriate for AT-cut crystal resonators, while polynomials of degree two may be applied for BT-cut crystal resonators. The description herein primarily refers to third-degree polynomials, but it will be appreciated that, if the resonator properties differ, (e.g. for a BT-cut crystal resonator or a MEMS resonator), the same approaches are still valid, but that the polynomial functions used may also be changed. For example, for a BT-cut crystal 101, the cubic term may be disregarded in the implementation of the learning algorithm (e.g. by considering a = 0). Conversely, some embodiments may go the other way and include a fourth-power term.

A number of different methods may be used by the learning unit 109 in different embodiments of the radio device 110. These are collectively referred to herein as “the learning algorithm”. Some non-exhaustive exemplary methods will be described in the following.

### Two-Polynomial Approach

In some embodiments, the learning unit 109 uses the insight that, since a, b and c in Equation (1) depend on the cutting angle θ of the crystal 101, a reference angle θ₀ can be chosen for the parameterisation in which c equals 0. This then allows Equation (1) to be rewritten as a function of the temperature of the crystal 101 and of the actual cutting angle, relative to the reference cutting angle θ₀, as follows:

$$\frac{Δ f}{f} \left(T , θ\right) = p \left(t , {θ}_{0}\right) + q \left(T , θ - {θ}_{0}\right)$$

where p and q are both polynomials.

If two polynomials, p₁ and p₂, of two different angles of the same type of cutting are known, then all of the other polynomials for that cutting type, within the appropriate temperature range, can be derived from the two polynomials by

$$r \left(T , α\right) = {p}_{1} \left(T , {θ}_{1}\right) + \left({p}_{2} \left(T , {θ}_{2}\right) - {p}_{1} \left(T , {θ}_{1}\right)\right) ∗ α$$

where θ₁ and θ₂ are two angles of the same type of cutting, and α is a coefficient, typically of value 0 ≤ α ≤ 1. However the range of α may differ from this depending on the desired set of polynomials. Although it is not necessary to know the cutting angles in this equation, for this approach to be successful the cutting angles must all be of the same type, e.g. the set of polynomials may apply only to AT-cut crystals.

For embodiments where this insight is used in the learning unit 109, the above relationship is used alongside two polynomials, which may be provided by the crystal manufacturer, defining minimum and maximum bounding curves for the temperature-dependent frequency error of the crystal 101.

For 0 ≤ α ≤ 1, the polynomial representing the frequency-temperature curve of the crystal unit 101, p_{XO}(T) will then lie be between these curves, i.e.

$$m i n \left({p}_{1} \left(T\right) , {p}_{2} \left(T\right)\right) \leq {p}_{X O} \left(T\right) \leq m a x \left({p}_{1} \left(T\right) , {p}_{2} \left(T\right)\right)$$

for all T in the relevant range, such as -60° C.≤T≤120° C.

Initially, the coefficients for the polynomial pₓₒ(T) are unknown.

When the RF receiver 105 of the radio device 110 receives a signal at a known frequency, the Fₑᵣᵣ value and the current temperature T of the crystal 101 can be saved as a measurement pair (Fₑᵣᵣ, T) for that temperature. A collection of these measurements, e.g. {(Fₑᵣᵣ₋₀, T₀), (Fₑᵣᵣ₋₁, T₁), ..., (F_{err-N},T_{N})} can be collected during receive operations over time and buffered in memory, as already described above.

Based on the two polynomials provided by the crystal manufacturer, and a measurement pair (Fₑᵣᵣ₋ₖ, Tₖ), the learning unit 109 may learn the parameters of the polynomial pₓₒ(T) = r(T, α) by assigning the value α in Equation (2) to be

$${α}_{k} = \frac{{F}_{e r r} - {p}_{1} \left(T\right)}{{p}_{2} \left(T\right) - {p}_{1} \left(T\right)}$$

thus yielding a model H(X_{N}) for the particular crystal 101 as

$${p}_{X O} \left(T\right) = {p}_{1} \left(T\right) + \left({p}_{2} \left(T\right) - {p}_{1} \left(T\right)\right) ∗ α$$

Once a plurality, n, of measurement pairs (Fₑᵣᵣ, T) have been collected and buffered (e.g. following multiple receive operations), the learning unit 109 may compute an average value of the individual αₖ values over the n sample pairs as

$${\text{α}}_{\text{ave}} = \left({\text{α}}_{0} + {\text{α}}_{1} + {\text{α}}_{2} + , … , + {\text{α}}_{\text{n-} 1}\right) / n$$

and apply this average value αₐᵥₑ to Equation (5) in place of just a single value αₖ.

This approach is relatively straightforward to implement in the learning unit 109.

### Least Squares

Some embodiments of the learning unit 109 may instead employ a least squares approach to fit a polynomial. This is done by minimising the (Euclidean) proper distance between the measurement data set and the polynomial, e.g. of the type in Equation (1) above.

A minimum of three measurement points must have been collected before a least-squares approach can be used in order to determine the three coefficients a, b and c uniquely. If a constant term, d, is solved too, then the minimum number of data points is four. The use of methods of least squares to solve frequency temperature curves provides can provide more filtering of data points, thereby potentially improving the quality of the resulting estimates.

In some embodiments, the learning unit 109 uses a gradient descent process, as described in more detail below. In other embodiments, the learning unit 109 uses a method of orthogonal polynomials with the Clenshaw recursion formula at a final step.

The least squares approach can be very precise for estimating relative frequency offsets at temperatures that are close to temperatures for which measured sample pairs have been obtained.

However, when the device 110 starts to receive data for the very first time after being initialised, the measurement points will initially cover only a short temperature interval of a whole operating range. In this case, a polynomial pₓₒ(T) calculated using least squares from these buffered data pairs may be only a loose approximation to the true frequency temperature curve.

To overcome this inaccuracy, in some embodiments, three extra auxiliary data points may be added to the buffer for training the model. These auxiliary {temperature, T; frequency-offset, F} pairs are not measurements, and are instead synthesised frequency values associated with minimum, maximum, and mid-point expected operational temperatures, Tₘᵢₙ, Tₘₐₓ, and T_{mid}.

The corresponding frequency errors, F_{err,min}, F_{err,max}, and F_{err,mid}, are calculated by the learning module 109 as

$${F}_{e r r , m i n} = {p}_{1} \left({T}_{m i n}\right) + \left({p}_{2} \left({T}_{m i n}\right) - {p}_{1} \left({T}_{m i n}\right)\right) ∗ γ$$

$${F}_{e r r , m i d} = {p}_{1} \left({T}_{m i d}\right) + \left({p}_{2} \left({T}_{m i d}\right) - {p}_{1} \left({T}_{m i d}\right)\right) ∗ γ$$

$${F}_{e r r , m i n} = {p}_{1} \left({T}_{m a x}\right) + \left({p}_{2} \left({T}_{m a x}\right) - {p}_{1} \left({T}_{m a x}\right)\right) ∗ γ$$

where p₁ and p₂ are manufacturer-provided curves as used in the inequality of Equation (3), and where y is an angle weight which may be determined in the same way as α in Equation (4) or (6).

In some embodiments, the values of Tₘᵢₙ, Tₘₐₓ, and T_{mid} may be chosen such that Tₘᵢₙ=-60.0° C., T_{mid}=+29.5° C. and Tₘₐₓ=+120.0° C. T_{mid} may be chosen such that it has a value close to the temperature at which p₁ and p₂ have a shared root, To, i.e. where p₁(T₀)=p₂(T₀)=0.

The three auxiliary data points may then be used with a single measured frequency-temperature pair as a four-point dataset on which the least squares fit is made, e.g. soon after the device 110 is first initialised.

As more data is collected by the system, and additional frequency-temperature pairs are added to the buffer, the auxiliary values may be removed from the training input to the model if appropriate. This may be done only after a condition is met, such as a minimum of ten measurements having been obtained, spanning an interval of at least 20° C. Then, for example, if, during operations, the device 110 records a frequency value at a temperature below -25° C., then the auxiliary data associated with Tₘᵢₙ may be removed from the active data points. Similarly, if the device 110 records a frequency value at a temperature above 85° C., then the auxiliary data associated with Tₘₐₓ may be removed from the active data points. This may be especially beneficial in the case where γ = 0.5, where it can be difficult for the learning unit 109 to obtain a final solution properly.

Alternatively, as the model is updated with measured values, an average value of γ may be calculated using Equation (6) from the measured values, without including the auxiliary data points. This average value of γ may then be used, instead of an initial constant value, to calculate updated frequency offsets for the auxiliary data points at Tₘᵢₙ, T_{mid}, and Tₘₐₓ, using the formulae above, and these points can then be included with the measured data when fitting the polynomial using a least squares approach.

### Gradient Descent

In some embodiments, updated parameters for a third-order polynomial model H(X_{N}), e.g. as in Equation (1) above, are calculated by solving a least squares problem using a gradient descent process. This is an iterative process in which the minimum of a cost function is sequentially determined for over a number of iterations.

The calculated values of a, b, c, and d when the cost function is minimised correspond to the values of a, b, c, and d that most closely match the actual properties of the crystal.

The least squares function to be solved can be represented using a cost function given as

$$C o s t = \frac{1}{M} {{\sum }_{i}^{M} \left\{{y}_{i} - \left[a {\left({T}_{i} - {T}_{0}\right)}^{3} + b {\left({T}_{i} - {T}_{0}\right)}^{2} + c \left({T}_{i} - {T}_{0}\right) + d\right]\right\}}^{2}$$

where:
M is the number of samples, indexed by i, that are used by the learning unit 109 to train the model;
yᵢ are the relative frequency errors, Fₑᵣᵣ, generated by automatic frequency control unit 105a (the learning unit 109 may calculate these Fₑᵣᵣ values from Tᵢ and the difference Fₑₛₜ - Fₑᵣᵣ output by the subtraction unit 115, or it may receive the values directly from the AFC unit 105a);
Tᵢ are the measured crystal temperatures corresponding to the respective yᵢ values; and
T₀ is a reference temperature for initial calibration data provided by the crystal manufacturer—e.g. T₀ = 27.5° C. for the data in FIG. 5.

Minimising the mean squared error through gradient descent can work well as it is a convex-shaped function and thus always finds the global minimum (i.e. no local minima); it can also converge rapidly by strongly penalising large errors.

In some embodiments, the learning model is initialised with a, b, c, d values based on data provided by the resonator manufacturer. In the case of crystal units, the manufacturer typically provides an extreme variation range specification for the a, b, c, d coefficients, for the particular type of crystal (i.e. for the particular cut angle).

When starting for the very first time, the learning unit 109 may initialise a, b, c and d to be the mean average (i.e. the midpoint) of the extremes provided by the manufacturer. The extremes, or the averages, may have been written to a memory of the device 110 during production (e.g. in the fabrication plant).

In some embodiments, the value of d is calibrated during production and may be treated as a constant during the learning process performed by the learning unit 109. However, other embodiments may treat d as an unknown parameter, along with a, b and c.

When employing a gradient descent approach, the minimisation of the cost function (i.e. minimising the mean squared error) requires calculating the gradient of the cost function with respect to each of the coefficients a, b and c (and optionally d).

In some embodiments, the learning unit 109 buffers a plurality of temperature-offset sample pairs, acquired over time, and uses all of these when minimising the cost function. In other embodiments, just the single most-recent temperature-offset sample pair is used, resulting in a simpler implementation.

The gradient is calculated by considering the partial derivative of the cost function with respect to each of a, b, and c, using the current values of a, b and c, as follows:

$$\begin{matrix}\frac{\partial }{\partial a} = - \left(\frac{2}{M}\right) {\sum }_{i}^{M} {\left({T}_{i} - {T}_{0}\right)}^{3} ∗ \\ \left\{{y}_{i} - \left[{a}_{c u r r} {\left({T}_{i} - {T}_{0}\right)}^{3} + {b}_{c u r r} {\left({T}_{i} - {T}_{0}\right)}^{2} + {c}_{c u r r} \left({T}_{i} - {T}_{0}\right) + d\right]\right\}\end{matrix}$$

$$\begin{matrix}\frac{\partial }{\partial b} = - \left(\frac{2}{M}\right) {\sum }_{i}^{M} {\left({T}_{i} - {T}_{0}\right)}^{2} ∗ \\ \left\{{y}_{i} - \left[{a}_{c u r r} {\left({T}_{i} - {T}_{0}\right)}^{3} + {b}_{c u r r} {\left({T}_{i} - {T}_{0}\right)}^{2} + {c}_{c u r r} \left({T}_{i} - {T}_{0}\right) + d\right]\right\}\end{matrix}$$

$$\begin{matrix}\frac{\partial }{\partial c} = - \left(\frac{2}{M}\right) {\sum }_{i}^{M} \left({T}_{i} - {T}_{0}\right) ∗ \\ \left\{{y}_{i} - \left[{a}_{c u r r} {\left({T}_{i} - {T}_{0}\right)}^{3} + {b}_{c u r r} {\left({T}_{i} - {T}_{0}\right)}^{2} + {c}_{c u r r} \left({T}_{i} - {T}_{0}\right) + d\right]\right\}\end{matrix}$$

The calculated gradients are used to determine the direction in which the values of the coefficients a, b, and c should be changed to minimise the error, with the magnitude of the change (i.e. the shift of value per iteration) determined by a parameter referred to the learning rate. The learning rate adjusts how much the coefficients are altered per iteration, and hence its value may be chosen to prevent the coefficients a, b, c, and d from growing too large too quickly. In some examples the learning rate is set equal to 0.0001.

Each time a new sample is obtained, new values of the coefficients a, b, and c are calculated from the current values as follows:

$${a}_{n e w} = {a}_{c u r r e n t} - l e a r n i n g R a t {e}^{3} ∗ \frac{\partial }{\partial a}$$

$${b}_{n e w} = {b}_{c u r r e n t} - l e a r n i n g R a t {e}^{2} ∗ \frac{\partial }{\partial b}$$

$${c}_{n e w} = {c}_{c u r r e n t} - l e a r n i n g R a t e ∗ \frac{\partial }{\partial c}$$

These calculations may be repeated a number of times for each new sample. Each iteration moves the cost function closer towards the minimum. In some embodiments, the number of iterations per sample is between 3 and 10, which is expected to give good performance in typical cases.

After progressively adjusting the values of a, b and c with each iteration, the resulting values of a, b and c are stored in memory as updated parameters for the model H.

In some embodiments, the updated value may be determined by using a plurality of buffered temperature-offset sample pairs in the gradient descent algorithm. The gradient descent then becomes a stochastic gradient descent because the calculated gradient will be an average gradient of the buffer samples. The buffered samples will ideally span a range of operating temperatures of the crystal 101. In some embodiments, the buffer has space for eight sample pairs; it may be filled in a first-in first-out fashion, or in a way that preserves a spread of samples over temperature, e.g. by dividing the full temperature range into a number of subranges and retaining the latest sample in each subrange.

When the device 110 is initialised for the very first time, the buffer will be empty. After a first sample pair has been collected, the gradient descent will be performed using just the one sample. As more samples are collected, all the available samples in the buffer are used, up to the maximum size of the buffer.

As explained above, in some alternative embodiments, the buffer may, on initialisation, be at least partly filled using a set of synthesised sample pairs, which may be calculated for predetermined temperature values from the average curves for the crystal type and/or the first one or more samples to be collected may be “mirrored” using a 180 degree rotation about the inflection point (e.g. 27.5 degrees in FIG. 5) to create a further set of synthesised sample pairs.

In some embodiments, the buffer may initially contain two pre-calculated sample pairs associated with the ‘extreme’ temperature subranges expected to be experienced by the radio device, for example at -60° C. and 120° C. The ‘extreme’ sample pairs may remain in the buffer until new data is recorded in similar temperature ranges, e.g. the sample pair associated with the low temperature extreme may be removed once data has been recorded at a temperature T < -20° C.

### Gradient Descent With Momentum

In some embodiments, the updated model parameters are determined by implementing a gradient descent process with a momentum term. In this approach, exponentially weighted averaging is introduced to the calculation of the parameters by storing the previous value of the parameters, for example parameter a, in addition to its current value, and then calculating each new value of the parameters, e.g. a_{new} in dependence on the current and previous values as follows:

$${a}_{n e w} = {a}_{c u r r e n t} - l e a r n i n g R a t {e}^{3} ∗ \left(β ∗ {a}_{p r e v i o u s} + \left(1 - β\right) ∗ \frac{\partial }{\partial a}\right)$$

The value of the hyperparameter β is set between zero and one. A value of β=0.9 has been found to work well in some situations.

Implementing a gradient momentum term allows the gradient descent to push a_{new} over difficult spots such as a local gradient of zero, and helps to stabilise the convergence process more generally.

Gradient momentum terms are implemented similarly for parameters b, c, to generate new values b_{new}, c_{new}.

### Gradient Descent With Bounds

In some embodiments, the updated model parameters are determined by implementing maximum and minimum bounding values on the coefficients a, b and c (and optionally d if it is not constant) when using gradient descent as described above. The manufacturer of the crystal resonator 101 may provide minimum and maximum values of each of a, b, c, and d.

Constraining the values of the parameters to remain within such minimum and maximum values can ensure that the learned temperature-offset curves do not go outside the original specification during the learning process.

The learning unit 109 may thus apply the following additional rules during each iteration of the gradient descent algorithm:

$$\text{if} {a}_{n e w} > m a x \text{\_} a \text{then} {a}_{n e w} : = m a x \text{\_} a ;$$

$$\text{if} {a}_{n e w} < m i n \text{\_} a \text{then} {a}_{n e w} : = m i n \text{\_} a$$

Similar rules can be applied to b and c.

Any of the embodiments described above may be adapted to additionally model one or more further variables, alongside temperature, such as atmospheric pressure or humidity.

It will be appreciated by those skilled in the art that the invention has been illustrated by describing one or more specific embodiments thereof, but is not limited to these embodiments; many variations and modifications are possible, within the scope of the accompanying claims.

1. A radio device comprising:
a radio transceiver;
a resonator or an interface to a resonator;
a temperature measurement unit or an interface to a temperature measurement unit;
a frequency synthesizer; and
a processing system,
wherein the radio device is configured to:
receive a temperature signal from the temperature measurement unit, representative of a measured temperature of the resonator;
use the temperature signal to determine an estimated frequency offset for the resonator, using a model, stored in a memory of the processing system, that relates frequency offset to temperature;
receive a periodic resonator signal from the resonator;
provide the periodic resonator signal to the frequency synthesizer;
control the frequency synthesizer, in dependence on the estimated frequency offset, to generate a periodic local signal from the periodic resonator signal;
receive a radio signal at the radio transceiver, wherein the radio signal comprises a periodic component having a received-signal frequency;
determine an error value representative of a difference between the received-signal frequency and a frequency of the periodic local signal; and
use the error value to update one or more parameters of the model stored in the memory.

2. The radio device of claim 1, wherein the radio device is further configured to: receive a second temperature signal from the temperature measurement unit, representative of a second measured temperature of the resonator;
use the second temperature signal and the model stored in the memory of the processing system to determine a second estimated frequency offset for the resonator; and
use the second estimated frequency offset for transmitting or receiving a radio signal.

3. The radio device of claim 1, wherein the radio device is configured to determine and use error values to update one or more parameters of the model repeatedly, at intervals, over time.

4. The radio device of claim 1, wherein the resonator is a quartz crystal resonator.

5. The radio device of claim 1, wherein the radio transceiver is configured to transmit a radio signal according to a half-duplex radio protocol.

6. The radio device of claim 1, wherein the radio transceiver implements an NB-IoT or half-duplex eMTC protocol.

7. The radio device of claim 1, wherein the periodic local signal is a local-oscillator signal that is input to a mixer in the radio transceiver.

8. The radio device of claim 1, wherein the radio device is a semiconductor chip and comprises an interface for connection to an off-chip resonator and an interface for connection to an off-chip temperature measurement unit.

9. The radio device of claim 1, wherein the radio device comprises the resonator and the temperature measurement unit, and wherein the temperature measurement unit is thermally coupled to the resonator.

10. The radio device of claim 1, wherein the model comprises one or more parameters for a predetermined equation, and wherein the processing system is configured to evaluate the equation numerically, by inputting the measured temperature, to determine the estimated frequency offset.

11. The radio device of claim 1, comprising one or more further environmental sensors, wherein the model additionally relates frequency offset to one or more additional environmental factors.

12. The radio device of claim 1, wherein the frequency synthesizer is a fractional frequency synthesizer and the processing system is configured to provide the estimated frequency offset, or a value derived therefrom, as input to a fractional divider of the fractional frequency synthesizer.

13. The radio device of claim 1, wherein the periodic component of the received radio signal is the carrier frequency of the radio signal.

14. The radio device of claim 1, wherein the radio transceiver comprises an automatic frequency control unit, and wherein the processing system is configured to generate the error value at least in part using the automatic frequency control unit.

15. The radio device of claim 1, wherein the processing system is configured to use a gradient descent process to minimize a cost function when updating the one or more parameters of the model.

16. The radio device of claim 1, wherein the model is a linear combination of two predetermined polynomial functions of temperature and wherein the processing system is configured to use the error value to update a parameter representing one or more coefficients of the linear combination.

17. The radio device of claim 1, wherein the processing system is configured to use a least-squares process to fit a polynomial function to a data set that includes the error value and the associated measured temperature.

18. The radio device of claim 1, wherein the processing system is configured to use, at times, one or more predetermined auxiliary values, in addition to one or more determined error values and measured temperatures, when updating the model.

19. A radio communication system comprising:
a radio device as claimed in claim 1; and
a remote radio transceiver, wherein the remote radio transceiver is configured to transmit said radio signal.

20. A method comprising:
receiving a temperature signal representative of a measured temperature of a resonator;
using the temperature signal to determine an estimated frequency offset for the resonator, using a model that relates frequency offset to temperature;
receiving a radio signal, wherein the radio signal comprises a periodic component having a received-signal frequency;
receiving a periodic resonator signal from the resonator;
using the estimated frequency offset to generate a periodic local signal from the periodic resonator signal;
determining an error value representative of a difference between the received-signal frequency and a frequency of the periodic local signal; and
using the error value to update one or more parameters of the model.
